(19) United States
(12) Patent Application Publication
(10) Pub. No.: US 2025/0020691 A1
(43) Pub. Date: Jan. 16, 2025

(54) ELECTRO-CONDUCTIVE CONTACT PIN, MANUFACTURING METHOD THEREFOR, AND ELECTRO-CONDUCTIVE CONTACT PIN MODULE

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Sung Hyun BYUN, Gyeonggi-do (KR)

(73) Assignee: POINT ENGINEERING CO., LTD., Chungcheongnam-do (KR)

(21) Appl. No.: 18/274,455

(22) PCT Filed: Jan. 25, 2022
(86) PCT No.: PCT/KR2022/001300

§ 371 Date: Jun. 27, 2024

(30) Foreign Application Priority Data
Jan. 29, 2021 (KR) 10-2021-0013285

(51) Int. Cl. G01R 1/067; G01R 1/073

(52) U.S. Cl. CPC G01R 1/06761; G01R 1/07307

(57) ABSTRACT

Proposed is an electro-conductive contact pin which can implement a narrow pitch between electro-conductive contact pins and prevent the electro-conductive contact pins from being short-circuited even upon contact between center portions of the electro-conductive contact pins, through a manufacturing method for an electro-conductive contact pin, the manufacturing method including a step of forming a module area including pin bodies and a support frame supporting the pin bodies through connecting portions, and a coating layer forming step of forming a coating layer on the pin bodies.

### CROSS-REFERENCE TO RELATED APPLICATION

This application is a 371 application of an international PCT application serial no. PCT/KR2022/001300, filed on Jan. 25, 2022, which claims the priority benefit of Korean application KR10-2021-0013285, filed on Jan. 29, 2021. The entirety of the above-mentioned patent application is hereby incorporated by reference herein and made a part of this specification.

### TECHNICAL FIELD

The present disclosure relates to an electro-conductive contact pin, a manufacturing method therefor, and an electro-conductive contact pin module.

### BACKGROUND ART

Electro-conductive contact pins are contact pins that can be used in probe cards or test sockets that contact and inspect an object. Hereinafter, contact pins of a probe card will be described as an example. A test for electrical characteristics of a semiconductor device is performed by approaching a wafer to a probe card having a plurality of contact pins and then bringing the respective contact pins into contact with corresponding electrode pads on the wafer. After the contact pins reach positions where they are brought into contact with the electrode pads, a process of further approaching the wafer to the probe card is performed. This process is called overdrive. Overdrive is a process that elastically deforms the contact pins. By overdrive, all contact pins can be reliably brought into contact with the electrode pads even when there is a height difference between the electrode pads or the contact pins. During overdrive, each contact pin is elastically deformed, and performs scrubbing while a front end of thereof moves on an electrode pad of the wafer. By such scrubbing, an oxide film on a surface of the electrode pad can be removed and contact resistance can be reduced thereby.

With the recent trend toward a narrower pitch of electrode pads, the pitch between electro-conductive contact pins has also become narrower. The electro-conductive pins are densely spaced apart from each other, and center body portions thereof are elastically bent during inspection. At this time, since each body portion independently performs inspection, adjacent body portions are brought into contact with each other and short-circuited.

In order to prevent undesirable contact between adjacent electro-conductive contact pins, a technique of installing an intermediate guide between upper and lower guides has been proposed. Although employing the intermediate guide can prevent contact between the pins, it is difficult to implement a narrow pitch, and it is also cumbersome to insert and install the pins into guide holes of the intermediate guide.

Moreover, most conventional techniques proposed so far have a limitation in improving the production efficiency of the electro-conductive contact pins and the handling of the electro-conductive contact pins. There is another limitation in improving inspection efficiency because end portions of the electro-conductive contact pins do not have functionality. There is a further limitation in improving the shape accuracy of the electro-conductive contact pins.

### DOCUMENTS OF RELATED ART

### Patent Documents

(Patent Document 1) European Patent No. 0915342
(Patent Document 2) Japanese Patent No. 4209696
(Patent Document 3) Japanese Patent Application Publication No. 2009-162483

### SUMMARY

Accordingly, the present disclosure has been made keeping in mind the above problems occurring in the related art, and an objective of the present disclosure is to realize a narrow pitch and to prevent electro-conductive contact pins from being short-circuited even when center portions thereof are brought into contact with each other.

Meanwhile, another objective of the present disclosure is to improve the production efficiency of electro-conductive contact pins and to improve the handling of the electro-conductive contact pins.

Meanwhile, another objective of the present disclosure is to improve the inspection efficiency by imparting functionality to end portions of electro-conductive contact pins.

Meanwhile, another objective of the present disclosure is to improve the shape accuracy of electro-conductive contact pins.

In order to accomplish the above objectives, the present disclosure provides a manufacturing method for an electro-conductive contact pin, the manufacturing method including: a step of forming a module area including pin bodies and a support frame supporting the pin bodies through connecting portions using a main metal layer, and a coating layer forming step of forming a coating layer on the pin bodies.

In addition, the step of forming the module area may include: a step of providing a seed layer on one surface of an anodic aluminum oxide plate made of an anodic aluminum oxide film; a step of forming openings by etching at least portions of the anodic aluminum oxide plate; and a step of forming the main coating layer in the openings by plating.

In addition, the step of forming the coating layer may include: a step of forming a masking agent on the anodic aluminum oxide plate and exposing surfaces of a first end portion and an intermediate portion of each of the pin bodies; a step of forming a functional coating on the surfaces of the first end portion and the intermediate portion of each of the pin bodies; a step of masking the first end portion of each of the pin bodies with the masking agent and then forming an insulating coating; a step of selectively removing the insulating coating except for the intermediate portion of each of the pin bodies; and a step of obtaining an electro-conductive contact pin module by removing all the remaining anodic aluminum oxide plate, masking agent, and seed layer.

In addition, the step of forming the coating layer may include: a step of forming a masking agent on upper and lower surfaces of the anodic aluminum oxide plate and exposing a surface of an intermediate portion of each of the pin bodies; a step of forming a functional coating on the surface of the intermediate portion of each of the pin bodies; a step of exposing a first end portion of each of the pin bodies by removing the insulating coating of the first end portion; a step of forming a functional coating on a surface of the first end portion of each of the pin bodies; a step of selectively removing the insulating coating of the second end portion of each of the pin bodies; and a step of obtaining an electro-conductive contact pin module by removing all the remaining anodic aluminum oxide plate, masking agent, and seed layer.

Meanwhile, according to another aspect of the present disclosure, there is provided a manufacturing method for an electro-conductive contact pin, the manufacturing method including: a module area forming step of integrally manufacturing pin bodies and a support frame supporting the pin bodies through connecting portions; and an insulating coating forming step of forming an insulating coating on a surface of an intermediate portion of each of the pin bodies.

In addition, the manufacturing method may further include a functional coating forming step of forming a functional coating on a surface of at least one end portion of each of the pin bodies.

In addition, the functional coating forming step may be performed before the step of forming the insulating coating, and the functional coating may be formed on the first end portion and the intermediate portion of each of the pin bodies.

In addition, the functional coating forming step may be performed after the step of forming the insulating coating, and the functional coating may be formed only on the first end portion of each of the pin bodies.

In addition, the module area forming step may include: a step of providing an anodic aluminum oxide mold having openings formed by providing a seed layer on a lower surface of an anodic aluminum oxide plate made of an anodic aluminum oxide film and then etching at least portions of the anodic aluminum oxide plate; and a step of forming a main metal layer in the openings by plating using the seed layer.

Meanwhile, according to another aspect of the present disclosure, there is provided an electro-conductive contact pin module, including: a support frame including connecting portions; and

electro-conductive contact pins provided in the support frame through the connecting portions. Here, each of the electro-conductive contact pins may include: a pin body including first and second end portions and an intermediate portion between the first and second end portions; an insulating coating formed on a surface of the intermediate portion of the pin body; and a functional coating formed on a surface of the first end portion of the pin body.

In addition, the functional coating may be formed on at least a portion of the support frame.

Meanwhile, according to another aspect of the present disclosure, there is provided an electro-conductive contact pin, including: a pin body including first and second end portions and an intermediate portion between the first and second end portions; an insulating coating formed on a surface of the intermediate portion of the pin body; and a functional coating formed on a surface of the first end portion of the pin body.

In addition, the functional coating may be continuously formed on the surfaces of the intermediate portion and the first end portion of the pin body, and may not be formed on a surface of the second end portion.

In addition, the functional coating may be formed only on the first end portion.

In addition, the functional coating may be made of Au.

In addition, a fine trench extending in a thickness direction of the electro-conductive contact pin may be provided on a side surface of the second end portion.

In addition, a side surface of the second end portion may be different in roughness range from a side surface of the first end portion.

In addition, a side surface of the second end portion may be different in roughness range from a side surface of the intermediate portion.

Meanwhile, according to another aspect of the present disclosure, there is provided an electro-conductive contact pin, including: a pin body including first and second end portions and an intermediate portion between the first and second end portions, and having a hole formed in the intermediate portion; and an insulating coating formed on a surface of the intermediate portion of the pin body. Here, the insulating coating may also be provided on an inner wall of the hole.

Meanwhile, according to another aspect of the present disclosure, there is provided an electro-conductive contact pin, including a pin body including first and second end portions and an intermediate portion between the first and second end portions. Here, the first end portion may be further provided with a functional coating on a surface thereof in addition to a material constituting the second end portion, and the intermediate portion may be further provided with an insulating coating on a surface thereof in addition to a material constituting the first end portion.

According to the present disclosure, it is possible to realize a narrow pitch and to prevent electro-conductive contact pins from being short-circuited even when center portions thereof are brought into contact with each other. In addition, it is possible to improve the production efficiency of the electro-conductive contact pins and to improve the handling of the electro-conductive contact pins. In addition, it is possible to improve the inspection efficiency by imparting functionality to end portions of the electro-conductive contact pins. In addition, it is possible to improve the shape accuracy of the electro-conductive contact pins.

### BRIEF DESCRIPTION OF THE DRAWINGS

FIGS. 1A, 1B, 1C, and 1D are views illustrating an electro-conductive contact pin according to a first embodiment of the present disclosure.

FIGS. 2A to 13B are views illustrating a manufacturing method for an electro-conductive contact pin according to the first embodiment of the present disclosure.

FIGS. 14A, 14B, 14C, and 14D are views illustrating an electro-conductive contact pin according to a second embodiment of the present disclosure.

FIGS. 15A to 27B are views illustrating a manufacturing method for an electro-conductive contact pin according to the second embodiment of the present disclosure.

FIG. 28 is an image illustrating a second end portion of the electro-conductive contact pin.

### DESCRIPTION OF THE EMBODIMENTS

Contents of the description below merely exemplify the principle of the present disclosure. Therefore, those of ordinary skill in the art may implement the theory of the present disclosure and invent various apparatuses which are included within the concept and the scope of the present disclosure even though it is not clearly explained or illustrated in the description. Furthermore, in principle, all the conditional terms and embodiments listed in this description are clearly intended for the purpose of understanding the concept of the present disclosure, and one should understand that the present disclosure is not limited to the exemplary embodiments and the conditions.

The above described objectives, features, and advantages will be more apparent through the following detailed description related to the accompanying drawings, and thus those of ordinary skill in the art may easily implement the technical spirit of the present disclosure.

The embodiments of the present disclosure will be described with reference to cross-sectional views and/or perspective views which schematically illustrate ideal embodiments of the present disclosure. For explicit and convenient description of the technical content, sizes or thicknesses of films and regions in the figures may be exaggerated. Therefore, variations from the shapes of the illustrations as a result, for example, of manufacturing techniques and/or tolerances, are to be expected. In addition, a limited number of molding products are illustrated in the drawings by way of example. Thus, the embodiments should not be construed as limited to the particular shapes of regions illustrated herein but are to include deviations in shapes that result, for example, from manufacturing.

Wherever possible, the same reference numerals will be used throughout different embodiments and the description to refer to the same or like elements or parts. In addition, the configuration and operation already described in other embodiments will be omitted for convenience.

An electro-conductive contact pin 100 according to an embodiment of the present disclosure is provided in an inspection apparatus and is used to transmit electrical signals by making electrical and physical contact with an object to be inspected. The inspection apparatus includes the electro-conductive contact pin 100 that makes contact with the object to be inspected. The inspection apparatus may be an inspection apparatus used in a semiconductor manufacturing process, for example, a probe card or a test socket. However, the inspection apparatus according to the embodiment of the present disclosure is not limited thereto, and includes any apparatus for checking whether an object to be inspected is defective by applying electricity.

Hereinafter, a probe card will be described as an example of the inspection apparatus. A test for electrical characteristics of a semiconductor device is performed by approaching a wafer to a probe card having a plurality of contact pins 100 and then bringing the respective contact pins 100 into contact with corresponding electrode pads on the wafer. After the contact pins 100 reach positions where they are brought into contact with the electrode pads, the wafer is further lifted to a predetermined height toward the probe card. This process is called overdrive. A probe head employed in the probe card may have a structure in which an upper guide plate and a lower guide plate are sequentially provided. The contact pins 100 are used while being inserted into guide holes of the upper and lower guide plates. The contact pins 100 have a structure elastically deformable between the upper guide plate and the lower guide plate. These contact pins 100 are adopted to constitute a vertical probe card 1. As an embodiment of the present disclosure, the contact pin 100 is described as having a pre-deformed structure, that is, a cobra pin shape. However, the embodiment of the present disclosure is not limited thereto, and also includes a structure for deforming a straight pin by using a moving plate.

The electro-conductive contact pin 100 according to the embodiment of the present disclosure includes a pin body 110. The pin body 110 includes first and second end portions 111 and 113 and an intermediate portion 112 between the first and second end portions 111 and 113. An insulating coating 120 is formed on a surface of the intermediate portion 112 of the pin body 110.

A manufacturing method for an electro-conductive contact pin 100 according to the embodiment of the present disclosure includes a module area forming step of integrally manufacturing pin bodies 110 and a support frame 200 supporting the pin bodies 110 through connecting portions 210, and an insulating coating forming step of forming an insulating coating 120 on a surface of an intermediate portion 112 of each of the pin bodies 110.

The module area forming step includes: a step of providing an anodic aluminum oxide mold having openings 11 formed by providing a seed layer 20 on a lower surface of an anodic aluminum oxide plate 10 made of an anodic aluminum oxide film and then etching at least portions of the anodic aluminum oxide plate 10; and a step of forming a main metal layer A in the openings 11 by plating using the seed layer 20.

According to an embodiment of the present disclosure, the step of forming the main metal layer A and the step of forming a coating layer B are performed in units of the anodic aluminum oxide plate 10. The anodic aluminum oxide plate 10 functions as a mold for forming the main metal layer A in manufacturing the pin body 110 of the electro-conductive contact pin 100, and functions to support an electro-conductive contact pin module 1000 in forming the coating layer B so that the coating layer B is collectively provided on a plurality of electro-conductive contact pins 100 connected to the support frame 200. The anodic aluminum oxide plate 10 is manufactured to have the same size as a silicon wafer so that the electro-conductive contact pin 100 can be manufactured using process equipment that processes the silicon wafer.

In addition, the manufacturing method for the electro-conductive contact pin 100 includes a functional coating forming step of forming a functional coating 130 on a surface of at least one end portion of each of the pin bodies 110. Here, the functional coating forming step may be a step that is performed before the step of forming the insulating coating and forms the functional coating 130 on a first end portion 111 and the intermediate portion 112 of each of the pin bodies 110. Alternatively, the functional coating forming step may be a step that is performed after the step of forming the insulating coating 120 and forms the functional coating 130 only on the first end portion 111 of each of the pin bodies 110.

First, a first embodiment of the present disclosure will be described.

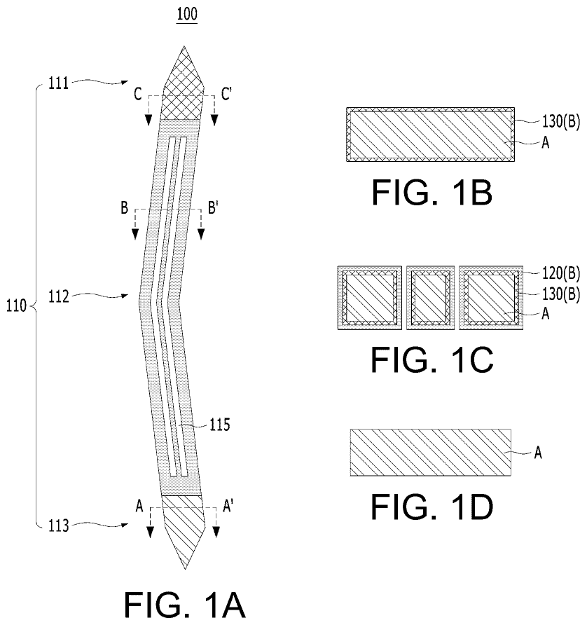

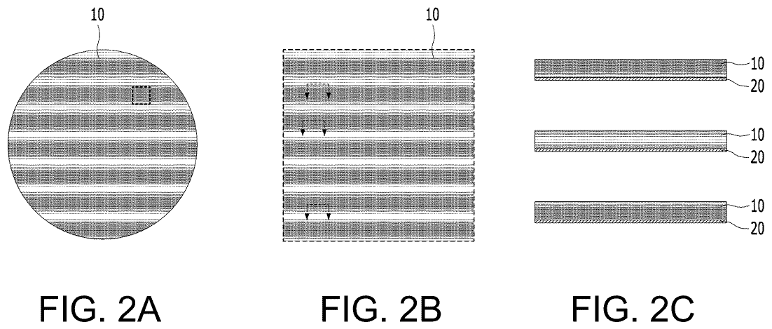

FIGS. 1A, 1B, 1C, and 1D are views illustrating an electro-conductive contact pin according to the first embodiment of the present disclosure, in which FIG. 1A is a plan view illustrating the electro-conductive contact pin, FIG. 1B is a sectional view taken along line A-A′ of FIG. 1A, FIG. 1C is a sectional view taken along line B-B′ of FIG. 1A, and FIG. 1D is a sectional view taken along line C-C′ of FIG. 1A. FIGS. 2A to 13B are views illustrating a manufacturing method for an electro-conductive contact pin according to the first embodiment of the present disclosure. In FIGS. 2A to 13B, FIG. A is a view illustrating an anodic aluminum oxide plate viewed from above, FIG. B is an enlarged view of a portion of FIG. A, and FIG. C is a sectional view of FIG. B.

Referring first to FIGS. 1A, 1B, 1C, and 1D, FIGS. 1A, 1B, 1C, and 1D are views illustrating the electro-conductive contact pin 100 according to the first embodiment of the present disclosure.

The electro-conductive contact pin 100 according to the first embodiment of the present disclosure includes a pin body 110. The pin body 110 includes first and second end portions 111 and 113 and an intermediate portion 112 between the first and second end portions 111 and 113.

The pin body 110 of the electro-conductive contact pin 100 is composed of a main metal layer A and a coating layer B. The main metal layer A is a portion that occupies most of the pin body 110, and the coating layer B is a portion that is additionally formed on a surface of the main metal layer A.

The main metal layer A of the pin body 110 may be made of a conductive material. Here, the conductive material may be at least one selected from the group consisting of platinum (Pt), rhodium (Rh), palladium (Pd), copper (Cu), silver (Ag), gold (Au), iridium (Ir), and an alloy of these metals, or the group consisting of a nickel-cobalt (NiCo) alloy, a palladium-cobalt (PdCo) alloy, a palladium-nickel (PdNi) alloy, and a nickel-phosphorus (NiP) alloy. The main metal layer A has a multilayer structure in which a plurality of conductive layers are stacked. The material of each of the conductive layers made of different materials may be selected from the group consisting of platinum (Pt), rhodium (Rh), palladium (Pd), copper (Cu), silver (Ag), gold (Au), iridium (Ir), and an alloy of these metals, or the group consisting of a palladium-cobalt (PdCo) alloy, a palladium-nickel (PdNi) alloy, and a nickel-phosphorus (NiP) alloy. As an example, the main metal layer A may have a multilayer structure in which first to fourth conductive layers are stacked. Here, the first conductive layer may be made of a platinum (Pt), the second conductive layer may be made of rhodium (Rh), the third conductive layer may be made of palladium (Pd), and the fourth conductive layer may be made of a nickel-cobalt (NiCo) alloy.

The coating layer B is a layer additionally formed on the surface of the main metal layer A, and includes an insulating coating 120 and a functional coating 130. The insulating coating 120 is formed on a surface of the intermediate portion 112 of the pin body 110, and the functional coating 130 is formed on a surface of at least one end portion of the pin body 110.

The electro-conductive contact pin 100 according to the first embodiment of the present disclosure includes the first and second end portions 111 and 113 and the intermediate portion 112. The first end portion 111 is further provided with the functional coating 130 on the surface thereof in addition to the material constituting the second end portion 113, and the intermediate portion 112 is further provided with the insulating coating 120 in addition to the material constituting the first end portion 111.

The insulating coating 120 prevents adjacent electro-conductive contact pins 100 from being brought into contact with each other and short-circuited during overdrive. In particular, even in a situation in which the electro-conductive contact pins 100 are arranged at a narrow pitch and thus are highly likely to be brought into contact with each other, the electro-conductive contact pins 100 are insulated from each other, thereby enabling stable inspection.

The insulating coating 120 may be an inorganic insulating coating or an organic insulating coating (including parylene resin), and may be formed using a coating method such as electrodeposition coating, deposition coating (CVD, ALD, etc.), or wet coating. However, in the case of a coating method used under high temperature conditions, since cracks may occur in the insulating coating 120 due to the difference in coefficient of thermal expansion between the insulating coating 120 and the main metal layer A after coating, it is preferable to use a coating method used under low or room temperature conditions.

The functional coating 130 is provided on at least one end portion of the electro-conductive contact pin 100 to reinforce or add a function to the end portion. For example, the functional coating 130 may be employed for the purpose of preventing oxidation and/or arcing of the end portion, may be employed for the purpose of preventing scratches on the object to be inspected, and may be employed for the purpose of improving current characteristics. In this case, materials suitable for each purpose may be selected. Meanwhile, the functional coating 130 may be employed for the purpose of preventing arcing from occurring upon contact between the electro-conductive contact pin 100 and a connection pad of a space transformer of a probe card. In this case, the functional coating 130 may be made of gold (Au).

The electro-conductive contact pin 100 includes the pin body 110 having holes 115. The holes 115 are formed in the intermediate portion 112 of the pin body 110. The insulating coating 120 formed on the surface of the intermediate portion 112 of the pin body 110 is also formed on inner walls of the holes 115.

The functional coating 130 is formed on the surface of the first end portion 111 of the pin body 110. The functional coating 130 is continuously formed on the surfaces of the intermediate portion 112 and the first end portion 111 of the pin body 110, and is not formed on the surface of the second end portion 113.

The first end portion 111 may be a portion that is brought into contact with the connection pad of the space transformer, and the second end portion 113 may be a portion that is brought into contact with the object to be inspected. When the functional coating 130 is formed on the surface of the second end portion 113, particles may be generated upon contact between the object to be inspected and the second end portion 113, and the generated particles may cause inspection errors. Therefore, in terms of preventing particle generation, the functional coating 130 may not be formed on the second end portion 113.

Hereinafter, the manufacturing method for the electro-conductive contact pin according to the first embodiment of the present disclosure will be described with reference to FIGS. 2A to 13B.

The manufacturing method for the electro-conductive contact pin according to the first embodiment includes a step of forming a module area including pin bodies 110 and a support frame 200 supporting the pin bodies 110 through connecting portions 210 using a main metal layer A, and a coating layer forming step of forming a coating layer B on the pin bodies 110.

First, with reference to FIGS. 2A to 4C, a description will be given of the step of forming the module area including the pin bodies 110 and the support frame 200 supporting the pin bodies 110 through the connecting portions 210 using the main metal layer A. The module area forming step includes: a step of providing a seed layer 20 on one surface of an anodic aluminum oxide plate made of an anodic aluminum oxide film; a step of forming openings 11 by etching at least portions of the anodic aluminum oxide plate 10; and a step of forming the main metal layer A in the openings 11 by plating.

Referring to FIGS. 2A to 2C, FIG. 2A is a plan view illustrating the anodic aluminum oxide plate 10, FIG. 2B is an enlarged view of a portion of FIG. 2A, and FIG. 2C is a sectional view illustrating a first end portion 111, an intermediate portion 112, and a second end portion 113 illustrated in FIG. 2B.

As illustrated in FIGS. 2A to 2C, the step of providing the seed layer 20 on one surface of the anodic aluminum oxide plate 10 made of the anodic aluminum oxide film is performed. The anodic aluminum oxide plate 10 may be made of the anodic aluminum oxide film. The anodic aluminum oxide film means a film formed by anodizing a metal as a base material, and pores mean holes formed in the process of forming the anodic aluminum oxide film by anodizing the metal. For example, when the metal as the base material is aluminum (Al) or an aluminum alloy, the anodization of the base material forms the anodic aluminum oxide film consisting of anodized aluminum (Al₂O₃) on a surface of the base material. The resulting anodic aluminum oxide film includes a barrier layer in which no pores are formed therein vertically, and a porous layer in which pores are formed therein. After removing the base material on which the anodic aluminum oxide film having the barrier layer and the porous layer is formed, only the anodic aluminum oxide film consisting of anodized aluminum (Al₂O₃) remains.

The anodic aluminum oxide film may have a structure in which the barrier layer formed during the anodization is removed to expose the top and bottom of the pores, or a structure in which the barrier layer formed during the anodization remains to close one of the top and bottom of the pores.

The anodic aluminum oxide film has a coefficient of thermal expansion of 2 to 3 ppm/° C. With this range, the anodic aluminum oxide film only undergoes a small amount of thermal deformation due to temperature when exposed to a high temperature environment. Thus, even when the electro-conductive contact pin 100 is manufactured in a high temperature environment, a precise electro-conductive contact pin 100 can be manufactured without thermal deformation.

Using the anodic aluminum oxide plate 10 made of the anodic aluminum oxide film instead of using a silicon wafer can improve the accuracy of the shape of the main metal layer A, and can help easily achieve selective etching of the anodic aluminum oxide film using an etchant.

The seed layer 20 is provided on one surface of the anodic aluminum oxide plate 10. The seed layer 20 may be made of copper (Cu), and may be formed by a deposition method. The seed layer 20 is used to improve the plating quality of the main metal layer A when the main metal layer A is formed using an electroplating method.

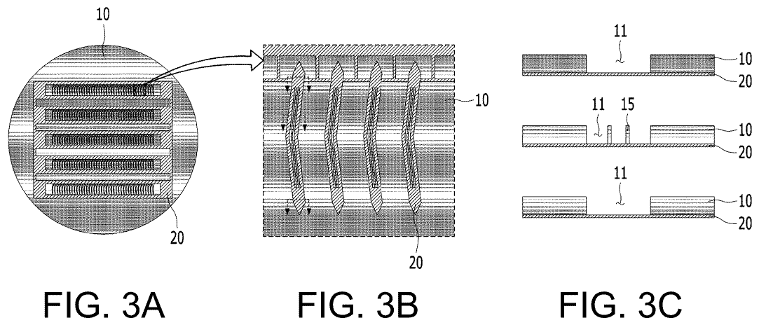

Next, referring to FIGS. 3A to 3C, FIG. 3A is a plan view illustrating the anodic aluminum oxide plate 10, FIG. 3B is an enlarged view of a portion of FIG. 3A, and FIG. 3C is a sectional view illustrating the first end portion 111, the intermediate portion 112, and the second end portion 113 illustrated in FIG. 3B.

As illustrated in FIGS. 3A to 3C, the step of forming the openings 11 by etching at least portions of the anodic aluminum oxide plate 10 is performed. The overall shape of the openings 11 corresponds to the shape of an electro-conductive contact pin module 1000. The openings 11 are formed in an area corresponding to the support frame 200 of the electro-conductive contact pin module 1000 and an area corresponding to electro-conductive contact pins 100.

Islands 15 made of the anodic aluminum oxide film are provided inside each of the openings 11 in the area corresponding to the electro-conductive contact pins 100. The islands 15 are areas where the anodic aluminum oxide film remains without being removed when the opening 11 is formed by etching a portion of the anodic aluminum oxide plate 10, and are anodic aluminum oxide film areas surrounded by the opening 11. The anodic aluminum oxide plate 10 may have a thickness in the range of 50 μm to 100 μm.

The openings 11 are formed by etching the anodic aluminum oxide plate 10. To this end, a photoresist may be provided on an upper surface of the anodic aluminum oxide plate 10 and patterned, and then the anodic aluminum oxide film in patterned and open areas may react with an etchant to form the openings 11. In detail, after a photosensitive material is provided on the upper surface of the anodic aluminum oxide plate 10 in a state before the openings 11 are formed, exposure and development processes may be performed. At least portions of the photosensitive material may be patterned and removed to form open areas through the exposure and development processes. Here, the photosensitive material remains on the areas that will later become the islands 15 without being removed. As a result of etching the anodic aluminum oxide plate 10 through the open areas where the photosensitive material is removed by the patterning process, the anodic aluminum oxide film around the areas that will later become the islands 15 is removed by the etchant to form the openings 11.

The shapes of the openings 10 and the islands 15 may be determined according to the shape of a pattern resulting from patterning the photosensitive material provided on the upper surface of the anodic aluminum oxide plate 10. The photosensitive material is not limited in dimensions and shapes of the areas to be patterned. Since the openings 11 and the islands 15 are formed by patterning the photosensitive material and etching the anodic aluminum oxide plate 10 through the areas removed by the patterning process, there is no limitation on the dimensions and shapes of the openings 11 and the islands 15. Each of the openings 11 later forms a pin body 110 of an electro-conductive contact pin 100. Since the openings 11 and the islands 15 are formed through the etching of the anodic aluminum oxide film as described above, the width of the pin body 110 including the width of holes 115 may be in the range of 1 μm to 100 μm, the width of the holes 115 may be in the range of 1 μm to 100 μm, more preferably 5 μm to 30 μm, and the total length of the electro-conductive contact pin 100 may be in the range of 1 mm to 10 mm.

An opening formed by a processing method using a laser or drill mainly has a circular cross-section or is formed in a shape that does not include a corner where surfaces meet. In addition, since the processing method using the laser or drill is difficult to form minute holes, and holes have to be formed at pitch intervals P considering mechanical errors, there are limitations on their dimension and shape. However, according to the embodiment of the present disclosure, the openings 11 may have angled corners, and the openings 11 can be formed without limiting their shape.

In addition, when the anodic aluminum oxide plate 10 is wet-etched with an etchant, openings 11 having vertical inner walls are formed. Therefore, the pin bodies 110 of the electro-conductive contact pins 100 have a rectangular longitudinal vertical section.

The anodic aluminum oxide plate 10 may be formed with a thickness in the range of 10 μm to 150 μm. In the case of using a photoresist mold instead of the anodic aluminum oxide plate 10, it is difficult to precisely and quickly manufacture openings having vertical side surfaces because the openings have to be formed in a thick photoresist through an exposure process. This method has limitations on increasing the thickness of the photoresist mold to equal to or greater than 70 μm. On the other hand, when the openings 11 are formed using the anodic aluminum oxide plate 10, the openings 11 having the vertical side surfaces can be formed precisely and quickly even when the thickness of the anodic aluminum oxide plate 10 is equal to or greater than 70 μm.

As described above, forming the main metal layer A using the anodic aluminum oxide film as a mold as compared to using the photoresist as a mold can improve the accuracy of the shape of the main metal layer A, so that pin bodies 110 having a precise microstructure can be manufactured.

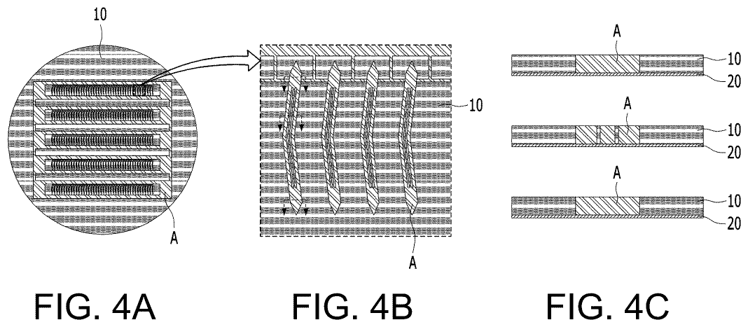

Next, referring to FIGS. 4A to 4C, FIG. 4A is a plan view illustrating the anodic aluminum oxide plate 10, FIG. 4B is an enlarged view of a portion of FIG. 4A, and FIG. 4C is a sectional view illustrating the first end portion 111, the intermediate portion 112, and the second end portion 113 illustrated in FIG. 4B.

As illustrated in FIGS. 4A to 4C, the step of forming the main metal layer A in the openings 11 by plating is performed. During electroplating, the main metal layer A is formed using the seed layer 20. After the plating process is completed, a planarization process is performed. The main metal layer A protruding from the upper surface of the anodic aluminum oxide plate 10 is removed and planarized through a chemical mechanical polishing (CMP) process.

Through the above-steps, the step of forming the module area including the pin bodies 110 and the support frame 200 supporting the pin bodies 110 through the connecting portions 210 using the main metal layer A is completed.

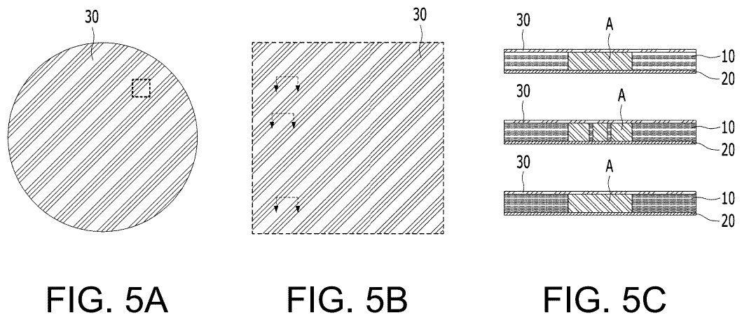

Next, a description will be given of the coating layer forming step of forming the coating layer B on the pin bodies 110 with reference to FIGS. 5A to 13B.

The coating layer forming step includes a step of forming an insulating coating 120 on the pin bodies 110 and a step of forming a functional coating 130 on the pin bodies 110. In detail, the coating layer forming step includes: a step of forming a masking agent 30 on the anodic aluminum oxide plate 10 and exposing surfaces of the first end portion 111 and the intermediate portion 112 of each of the pin bodies 110; a step of forming the functional coating 130 on the surfaces of the first end portion 111 and the intermediate portion 112 of each of the pin bodies 110; a step of masking the first end portion 111 of each of the pin bodies 110 with the masking agent 30 and then forming the insulating coating 120; a step of selectively removing the insulating coating 120 except for the intermediate portion 112 of each of the pin bodies 110; and a step of obtaining an electro-conductive contact pin module 1000 by removing all the anodic aluminum oxide plate 10, the masking agent 30, and the seed layer 20.

Referring to FIGS. 5A to 5C, FIG. 5A is a plan view illustrating the anodic aluminum oxide plate 10, FIG. 5B is an enlarged view of a portion of FIG. 5A, and FIG. 5C is a sectional view illustrating the first end portion 111, the intermediate portion 112, and the second end portion 113 illustrated in FIG. 5B.

As illustrated in FIGS. 5A to 5C, the step of forming the masking agent 30 on the anodic aluminum oxide plate 10 is performed. The masking agent 30 may be a photosensitive material or an insulating material. The masking agent 30 may be, for example, a photoresist. The masking agent 30 is entirely applied on the upper surfaces of the anodic aluminum oxide plate 10 and the main metal layer A so that the main metal layer A is not exposed to the outside.

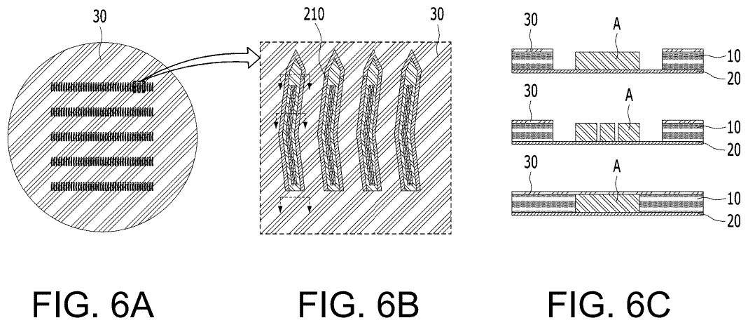

Referring to FIGS. 6A to 6C, FIG. 6A is a plan view illustrating the anodic aluminum oxide plate 10, FIG. 6B is an enlarged view of a portion of FIG. 6A, and FIG. 6C is a sectional view illustrating the first end portion 111, the intermediate portion 112, and the second end portion 113 illustrated in FIG. 6B.

As illustrated in FIGS. 6A to 6C, the step of exposing the surfaces of the first end portion 111 and the intermediate portion 112 of each of the pin bodies 110 by removing the masking agent 30 on the surfaces of the first end portion 111 and the intermediate portion 112 of each of the pin bodies 110 is performed. First, the masking agent 30 is subjected to exposure and development processes to form an open area through which surface areas of the first end portion 111 and the intermediate portion 112 of each of the pin bodies 110 are exposed. The open area is formed in a size larger than the shape of each of the pin bodies 110 so that the coating layer B which will be described later is also formed on side surfaces of the pin body 110. Then, the anodic aluminum oxide film in the open area is removed using an etchant. At this time, since the etchant is a solution that selectively reacts only with the anodic aluminum oxide film, the seed layer 20 thereunder remains unreacted and an upper portion of the seed layer 20 is exposed.

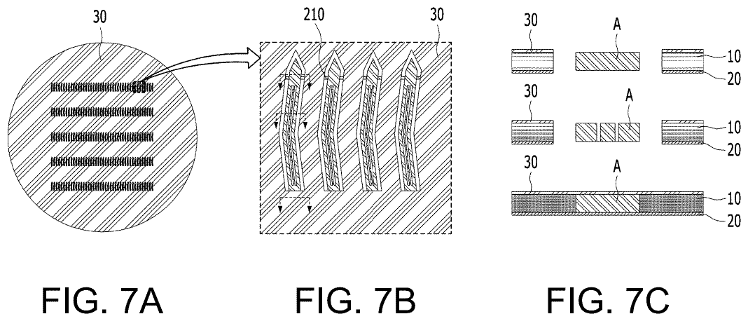

Referring to FIGS. 7A to 7C, FIG. 7A is a plan view illustrating the anodic aluminum oxide plate 10, FIG. 7B is an enlarged view of a portion of FIG. 7A, and FIG. 7C is a sectional view illustrating the first end portion 111, the intermediate portion 112, and the second end portion 113 illustrated in FIG. 7B.

As illustrated in FIGS. 7A to 7C, the step of removing the seed layer 20 present on lower surfaces of the first end portion 111 and the intermediate portion 112 of each of the pin bodies 110 is performed. With this process, the first end portion 111 and the intermediate portion 112 of each of the pin bodies 110 have a structure in which all the upper, lower, and side surfaces thereof are exposed.

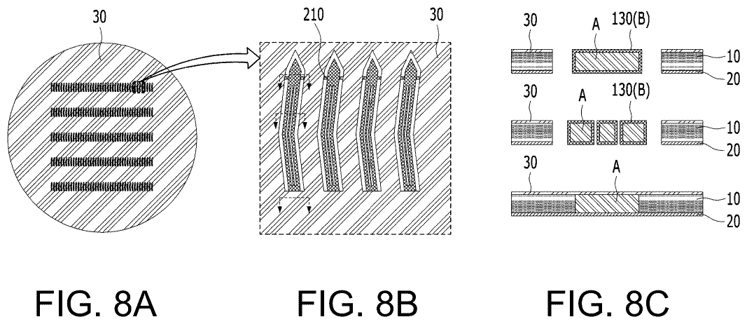

Referring to FIGS. 8A to 8C, FIG. 8A is a plan view illustrating the anodic aluminum oxide plate 10, FIG. 8B is an enlarged view of a portion of FIG. 8A, and FIG. 8C is a sectional view illustrating the first end portion 111, the intermediate portion 112, and the second end portion 113 illustrated in FIG. 8B.

As illustrated in FIGS. 8A to 8C, the step of forming the functional coating 130 on the surfaces of the first end portion 111 and the intermediate portion 112 of each of the pin bodies 110 is performed. The functional coating 130 is formed on the upper, lower, and side surfaces of the first end portion 111 and the intermediate portion 112 of each of the pin bodies 110 to surround the pin body 110. The functional coating 130 may be formed on the surfaces of the first end portion 111 and the intermediate portion 112 of each of the pin bodies 110 by electroplating. Since support frames 200 of the module area are connected to each other through the main metal layer A, when an electrode for electroplating is connected to the main metal layer A of a part of the module area, the functional coating 130 is collectively formed on the surfaces of the first end portion 111 and the intermediate portion 112 of each of the pin bodies 110.

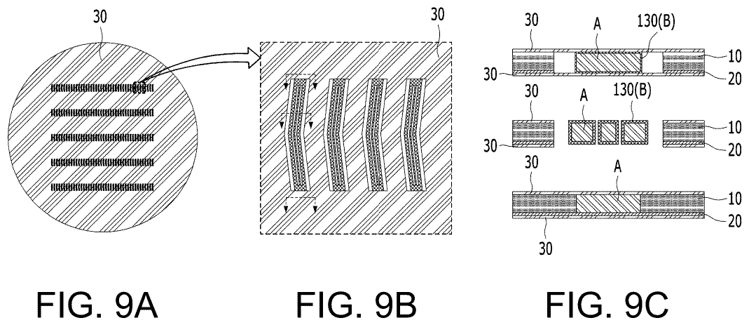

Referring to FIGS. 9A to 9C, FIG. 9A is a plan view illustrating the anodic aluminum oxide plate 10, FIG. 9B is an enlarged view of a portion of FIG. 9A, and FIG. 9C is a sectional view illustrating the first end portion 111, the intermediate portion 112, and the second end portion 113 illustrated in FIG. 9B.

As illustrated in FIGS. 9A to 9C, the step of masking the first end portion 111 of each of the pin bodies 110 with the masking agent 30 is performed. The masking agent 30 is also formed on a lower surface of the anodic aluminum oxide plate 10 except for the intermediate portion 112.

Here, it is important that the masking agent 30 formed on the upper surface of the first end portion 111 does not pass over the connecting portions 210 of the support frame 200. The connecting portions 210 have to be configured to allow the electro-conductive contact pins 100 to be easily removed from the support frame 200, while functioning to fix the electro-conductive contact pins 100 to the support frame 200 until the electro-conductive contact pins 100 are removed from the support frame 200. To this end, the connecting portions 210 include horizontally thin strip-shaped portions connecting adjacent electro-conductive contact pins 100 disposed in the horizontal direction. Here, the masking agent 30 covers the horizontally thin strip-shaped connecting portions 210 (more specifically, horizontal connecting portions 211 which will be described later) so as not to be entirely exposed. In other words, the horizontally thin strip-shaped connecting portions 210 (i.e., the horizontal connecting portions 211) are partially exposed or entirely covered. With this configuration, the insulating coating 120 which will be described later can be prevented from penetrating into the first end portion 111.

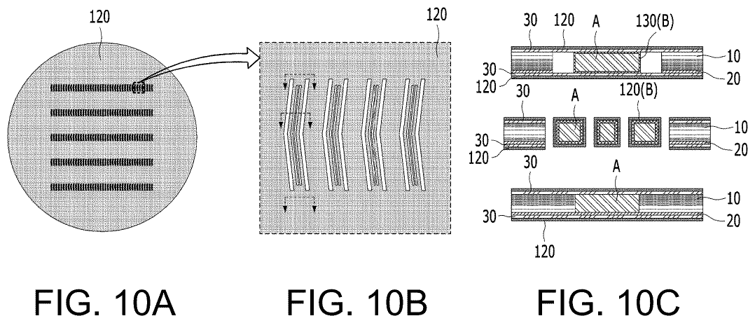

Referring to FIGS. 10A to 10C, FIG. 10A is a plan view illustrating the anodic aluminum oxide plate 10, FIG. 10B is an enlarged view of a portion of FIG. 10A, and FIG. 10C is a sectional view illustrating the first end portion 111, the intermediate portion 112, and the second end portion 113 illustrated in FIG. 10B.

As illustrated in FIGS. 10A to 10C, the step of forming the insulating coating 120 is performed. The insulating coating 120 may be an inorganic insulating coating or an organic insulating coating (including parylene resin), and may be formed using a coating method such as electrodeposition coating, deposition coating (CVD, ALD, etc.), or wet coating. The insulating coating 120 is entirely formed on the exposed surfaces. At this time, the connecting portion 210 (horizontal connecting portions 211) of the support frame 200 functions as a barrier preventing the insulating coating 120 from penetrating into the first end portion 111. The insulating coating 120 is formed on the surface of the intermediate portion 112 of each of the pin bodies 110, and is also formed on inner walls of holes 115 formed in the intermediate portion 112. The intermediate portion 112 of each of the pin bodies 110 has a structure in which the functional coating 130 is formed on the main metal layer A and the insulating coating 120 is formed on the functional coating 130. The insulating coating 120 may also be formed on the upper and lower surfaces of the anodic aluminum oxide plate 10.

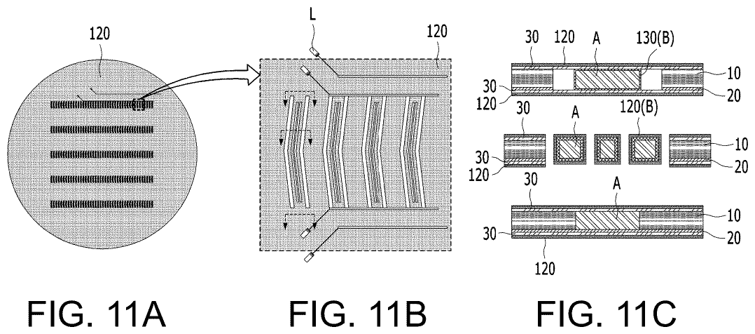

Referring to FIGS. 11A to 11C, FIG. 11A is a plan view illustrating the anodic aluminum oxide plate 10, FIG. 11B is an enlarged view of a portion of FIG. 11A, and FIG. 11C is a sectional view illustrating the first end portion 111, the intermediate portion 112, and the second end portion 113 illustrated in FIG. 11B.

As illustrated in FIGS. 11A to 11C, the step of selectively removing the insulating coating 120 except for the intermediate portion 112 of each of the pin bodies 110 is performed. In the previous step, the insulating coating 120 is formed not only on the intermediate portion 112 of each of the pin bodies 110 but also on the upper and lower surfaces of the peripheral area thereof. Therefore, a process of removing the insulating coating 120 in the area except for the intermediate portion 112 of each of the pin bodies 110 is performed. A boundary area separating the insulating coating 120 of the intermediate portion 112 from the peripheral area is formed using a laser L. Here, the boundary area may be formed using a sandblasting method other than the laser L, and other physical or chemical methods may be used. The masking agent 30 is exposed through the boundary area. The masking agent 30 is removed by injecting a masking agent etchant into the boundary area. The insulating coating 120 to be removed is removed together with the removal of the masking agent 30. After that, the remaining anodic aluminum oxide plate 10 and seed layer 20 are all removed using respective etchants.

Through the above steps, the electro-conductive contact pin module 1000 including the electro-conductive contact pins 100 provided in the support frame 200 through the connecting portions 210 is obtained.

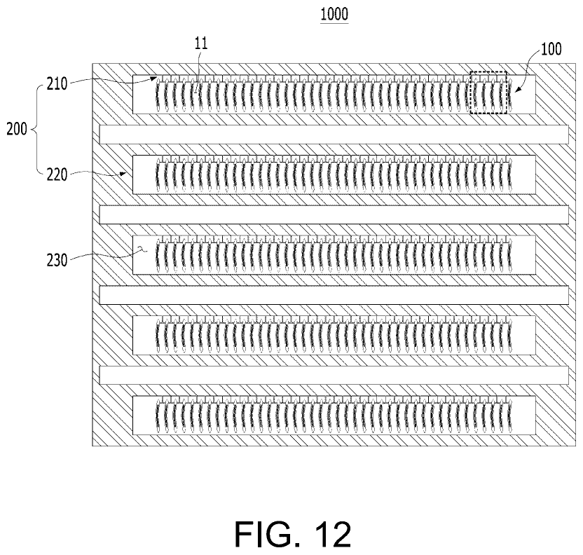

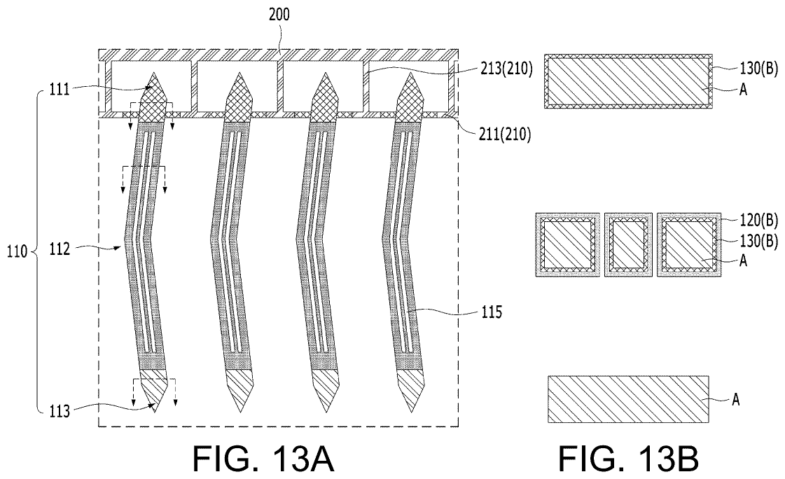

FIG. 12 is a plan view illustrating an electro-conductive contact pin module 1000. FIG. 13A is an enlarged view of a portion of FIG. 12, and FIG. 13B is a sectional view illustrating a first end portion 111, an intermediate portion 112, and a second end portion 113 illustrated in FIG. 13A.

Referring to FIG. 12 and FIGS. 13A and 13B, the electro-conductive contact pin module 1000 includes a support frame 200 having connecting portions 210, and electro-conductive contact pins 100 provided in the support frame 200 through the connecting portions 210.

The support frame 200 includes the connecting portions 210 connected to the electro-conductive contact pins 100, and a main body 220. Since the support frame 200 is formed together with the formation of a main metal layer A of a pin body 110 of each of the electro-conductive contact pins 100, the material of the support frame 200 is the same as that of the main metal layer A of the pin body 110.

The support frame 200 includes at least one pin receiving portion 230. Referring to FIG. 12, a plurality of pin receiving portions 230 are disposed while being spaced apart in the vertical direction. In the drawing, five pin receiving portions 230 are illustrated. Each of the pin receiving portions 230 is provided with the connecting portions 210, and a plurality of electro-conductive contact pins 100 are disposed in a row between the connecting portions 210 of each of the pin receiving portions 230.

In the pin receiving portion 230, the first end portion 111 of each of the electro-conductive contact pins 100 is connected to the connecting portions 210 and fixed to the main body 220, and the second end portion 113 thereof is a free end. The connecting portions 210 include horizontal connecting portions 211 and vertical connecting portions 213. The horizontal connecting portions 211 are portions that are connected to opposite side surfaces of the electro-conductive contact pins 100, and the vertical connecting portions 213 are portions that connect the horizontal connecting portions 211 to the main body 220. At least a portion of the first end portion 111 of each of the electro-conductive contact pins 100 is located in each of spaces formed by the horizontal connecting portions 211, the vertical connecting portions 213, and the main body 220. With this configuration, when the electro-conductive contact pin 100 needs to be manually removed from the support frame 200, the electro-conductive contact pin 100 can be easily removed by applying a separation force that twists the first end portion 111 to be separated from the connecting portions 210 while clamping the second end portion 113. In addition, even when the electro-conductive contact pin 100 needs to be removed from the support frame 200 using a laser or the like, the electro-conductive contact pin 100 can be easily removed from the support frame 200 due to a minimized laser irradiation area.

The main body 220 is formed with a large area so that an electrode for plating is easily connected to the main body 220 and a plating current is uniformly supplied to each of the pin receiving portions 230. Since a uniform plating current can be applied to each of the electro-conductive contact pins 100 during plating by connecting the electrode for plating to the main body 220, the electro-conductive contact pins 100 of uniform quality can be obtained.

Each of the electro-conductive contact pins 100 constituting the electro-conductive contact pin module 1000 includes the pin body 110 including the first and second end portions 111 and 113 and the intermediate portion 112 between the first and second end portions 111 and 113, an insulating coating 120 formed on a surface of the intermediate portion 112 of the pin body 110, and a functional coating 130 formed on a surface of the first end portion 111 of the pin body 110.

Holes 115 are provided in the intermediate portion 112 of the pin body 110. The functional coating 130 and the insulating coating 120 are sequentially provided on inner walls of the holes 115.

The functional coating 130 is formed on at least a portion of the support frame 200. As illustrated in FIGS. 13A and 13B, the connecting portions 210 of the support frame 200 are composed of the main metal layer A, and the functional coating 130 is coated on at least a portion of each of the connecting portions 210 connected to the first end portion 111. The electro-conductive contact pin 100 has a shape that can be easily removed from the support frame 200. With this configuration in which the functional coating 130 is coated on at least the portion of each of the connecting portions 210, even when a burr is generated when the electro-conductive contact pin 100 is removed from the connecting portions 210 and sticks to the first end portion 111, the burr does not cause deterioration of the function of the first end portion 111 because it has the same component as that of the first end portion 111.

The electro-conductive contact pin 100 according to the first embodiment of the present disclosure includes the first and second end portions 111 and 113 and the intermediate portion 112 between the first and second end portions 111 and 113. The first end portion 111 is further provided with the functional coating 130 on the surface thereof in addition to the material constituting the second end portion 113, and the intermediate portion 112 is further provided with the insulating coating 120 in addition to the material constituting the first end portion 111.

The functional coating 130 may be made of a material having higher electrical conductivity than the average electrical conductivity of the main metal layer A, and may be made of, for example, gold (Au). The main metal layer A is a portion that occupies most of the volume of the pin body 110 and is made of a material that allows the electro-conductive contact pin 100 to be elastically deformed for a long period of time. Therefore, the average electrical conductivity of the main metal layer A is lower than that of the functional coating 130 made of gold (Au). With this configuration in which the functional coating 130 made of gold (Au) is entirely formed on the intermediate portion 112 and the first end portion 111, the electrical resistance to a current flowing through the electro-conductive contact pin 100 can be reduced. In addition, the functional coating 130 provided on the first end portion 111 functions to prevent arcing from occurring upon contact between the first end portion 111 and a connection pad of a space transformer. However, due to low hardness thereof, the functional coating 130 provided on the intermediate portion 112 may generate particles and may cause a short circuit between adjacent electro-conductive contact pins 100 upon contact. Therefore, the insulating coating 120 is additionally provided on the intermediate portion 112. Meanwhile, the second end portion 113 is composed of only the main metal layer A without the coating layer B, that is, the insulating coating 120 and the functional coating 130, formed thereon. The functional coating 130 may also be formed on the second end portion 113, but when the functional coating 130 is made of gold (Au), particles may be generated upon contact between the second end portion 113 and an object to be inspected. Therefore, it is preferable that the functional coating 130 is not formed on the second end portion 113 in terms of preventing particle generation. However, when the functional coating 130 is not made of gold (Au) and is necessary in terms of a function to be exhibited, the functional coating 130 may also be provided on the second end portion 113.

Next, a second embodiment according to the present disclosure will be described. However, the embodiments described below will be mainly described in terms of characteristic elements in comparison with the first embodiment, and descriptions of the same or similar elements to the first embodiment will be omitted.

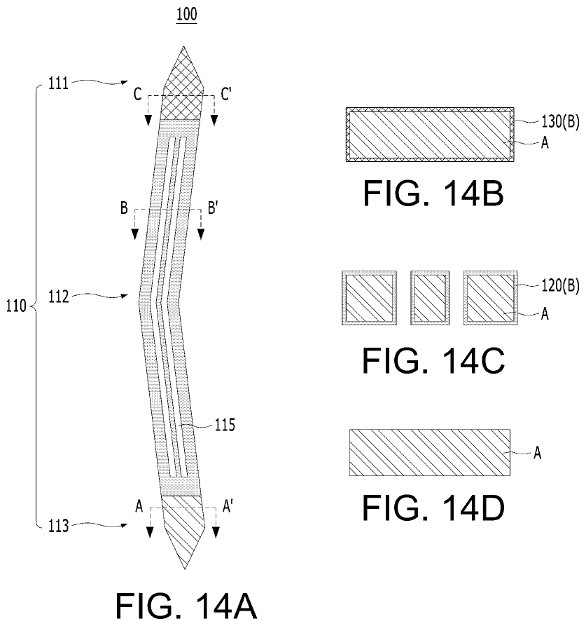

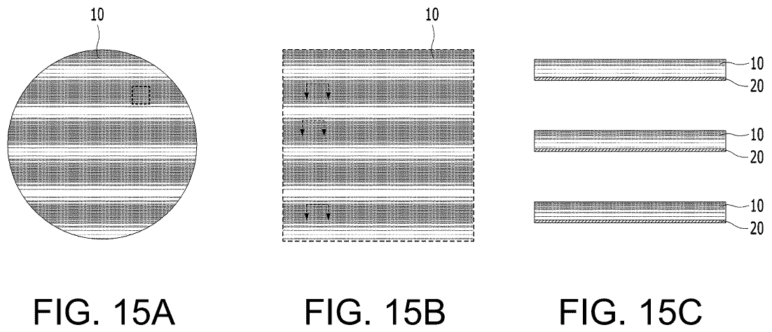

FIGS. 14A, 14B, 14C, and 14D are views illustrating an electro-conductive contact pin according to the second embodiment of the present disclosure, in which FIG. 14A is a plan view illustrating the electro-conductive contact pin, FIG. 14B is a sectional view taken along line A-A′ of FIG. 14A, FIG. 14C is a sectional view taken along line B-B′ of FIG. 14A, and FIG. 14C is a sectional view taken along line C-C′ of FIG. 14A. FIGS. 15A to 27B are views illustrating a manufacturing method for an electro-conductive contact pin according to the second embodiment of the present disclosure. In FIGS. 15A to 27B, FIG. A is a view illustrating an anodic aluminum oxide plate viewed from above, FIG. B is an enlarged view of a portion of FIG. A, and FIG. C is a sectional view of FIG. B.

Referring first to FIGS. 14A, 14B, 14C, and 14D, FIGS. 14A, 14B, 14C, and 14D are views illustrating the electro-conductive contact pin 100 according to the second embodiment of the present disclosure.

The electro-conductive contact pin 100 according to the second embodiment of the present disclosure includes first and second end portions 111 and 113 and an intermediate portion 112. The first end portion 111 is further provided with a functional coating 130 on a surface thereof in addition to the material constituting the second end portion 113, and the intermediate portion 112 is further provided with an insulating coating 120 in addition to the material constituting the second end portion 113.

The electro-conductive contact pin 100 includes the pin body 110 having holes 115. The holes 115 are formed in the intermediate portion 112 of the pin body 110. The insulating coating 120 formed on the surface of the intermediate portion 112 of the pin body 110 is also formed on inner walls of the holes 115. The functional coating 130 is formed on the surface of the first end portion 111 of the pin body 110. The functional coating 130 is formed on the surface of the first end portion 111 of the pin body 110 and is not formed on the surface of the second end portion 113.

Hereinafter, the manufacturing method for the electro-conductive contact pin according to the second embodiment of the present disclosure will be described with reference to FIGS. 15A to 27B.

The manufacturing method for the electro-conductive contact pin according to the second embodiment includes a step of forming a module area including pin bodies 110 and a support frame 200 supporting the pin bodies 110 through connecting portions 210 using a main metal layer A, and a coating layer forming step of forming a coating layer B on the pin bodies 110.

First, with reference to FIGS. 15A to 17C, a description will be given of the step of forming the module area including the pin bodies 110 and the support frame 200 supporting the pin bodies 110 through the connecting portions 210 using the main metal layer A. The module area forming step includes: a step of providing a seed layer 20 on one surface of an anodic aluminum oxide plate made of an anodic aluminum oxide film; a step of forming openings 11 by etching at least portions of the anodic aluminum oxide plate 10; and a step of forming the main metal layer A in the openings 11 by plating.

Referring to FIGS. 15A to 15C, FIG. 15A is a plan view illustrating the anodic aluminum oxide plate 10, FIG. 15B is an enlarged view of a portion of FIG. 15A, and FIG. 15C is a sectional view illustrating a first end portion 111, an intermediate portion 112, and a second end portion 113 illustrated in FIG. 15B.

As illustrated in FIGS. 15A to 15C, the step of providing the seed layer 20 on one surface of the anodic aluminum oxide plate 10 made of the anodic aluminum oxide film is performed. The seed layer 20 is provided on one surface of the anodic aluminum oxide plate 10. The seed layer 20 may be made of copper (Cu), and may be formed by a deposition method.

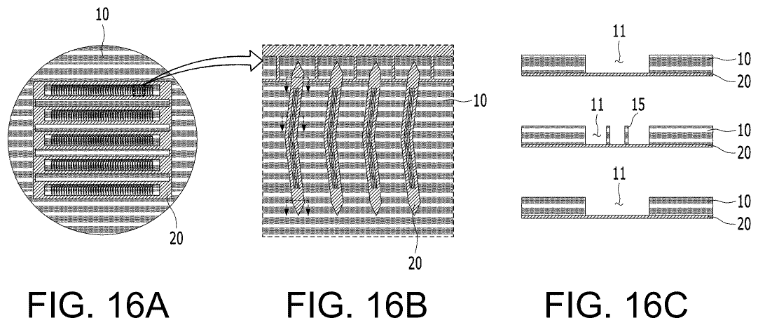

Next, referring to FIGS. 16A to 16C, FIG. 16A is a plan view illustrating the anodic aluminum oxide plate 10, FIG. 16B is an enlarged view of a portion of FIG. 16A, and FIG. 16C is a sectional view illustrating the first end portion 111, the intermediate portion 112, and the second end portion 113 illustrated in FIG. 16B.

As illustrated in FIGS. 16A to 16C, the step of forming the openings 11 by etching at least portions of the anodic aluminum oxide plate 10 is performed. The overall shape of the openings 11 corresponds to the shape of an electro-conductive contact pin module 1000. The openings 11 are formed in an area corresponding to the support frame 200 of the electro-conductive contact pin module 1000 and an area corresponding to electro-conductive contact pins 100.

Islands 15 made of the anodic aluminum oxide film are provided inside each of the openings 11 in the area corresponding to the electro-conductive contact pins 100. The islands 15 are areas where the anodic aluminum oxide film remains without being removed when the opening 11 is formed by etching a portion of the anodic aluminum oxide plate 10, and are anodic aluminum oxide film areas surrounded by the opening 11. The anodic aluminum oxide plate 10 may have a thickness in the range of 50 μm to 100 μm.

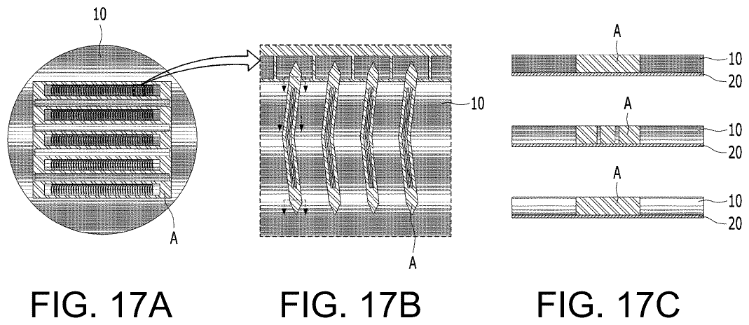

Next, referring to FIGS. 17A to 17C, FIG. 17A is a plan view illustrating the anodic aluminum oxide plate 10, FIG. 17B is an enlarged view of a portion of FIG. 17A, and FIG. 17C is a sectional view illustrating the first end portion 111, the intermediate portion 112, and the second end portion 113 illustrated in FIG. 17B.

As illustrated in FIGS. 17A to 17C, the step of forming the main metal layer A in the openings 11 by plating is performed. During electroplating, the main metal layer A is formed using the seed layer 20. After the plating process is completed, a planarization process is performed. The main metal layer A protruding from the upper surface of the anodic aluminum oxide plate 10 is removed and planarized through a chemical mechanical polishing (CMP) process.

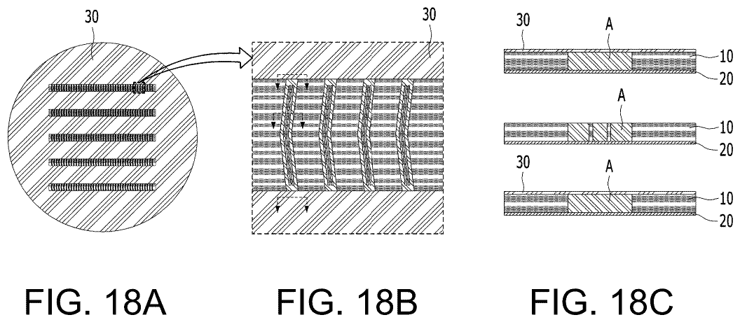

Next, a description will be given of the coating layer forming step of forming the coating layer B on the pin bodies 110 with reference to FIGS. 18A to 27B. The coating layer forming step includes a step of forming an insulating coating 120 on the pin bodies 110 and a step of forming a functional coating 130 on the pin bodies 110. In detail, the coating layer forming step includes: a step of forming a masking agent 30 on upper and lower surfaces of the anodic aluminum oxide plate 10 and exposing a surface of the intermediate portion 112 of each of the pin bodies 110; a step of forming the insulating coating 120 on the surface of the intermediate portion 112 of each of the pin bodies 110; a step of exposing the first end portion 111 of each of the pin bodies 110 by removing the insulating coating 120 on the first end portion 111; a step of forming the functional coating 130 on a surface of the first end portion 111 of each of the pin bodies 110; a step of selectively removing the insulating coating 120 on the intermediate portion 112 of each of the pin bodies 110; and a step of obtaining an electro-conductive contact pin module 1000 by removing all the anodic aluminum oxide plate 10, the masking agent 30, and the seed layer 20.

Referring to FIGS. 18A to 18C, FIG. 18A is a plan view illustrating the anodic aluminum oxide plate 10, FIG. 18B is an enlarged view of a portion of FIG. 18A, and FIG. 18C is a sectional view illustrating the first end portion 111, the intermediate portion 112, and the second end portion 113 illustrated in FIG. 18B.

As illustrated in FIGS. 18A to 18C, the step of forming the masking agent 30 on the upper and lower surfaces of the anodic aluminum oxide plate 10 and patterning the masking agent 30 is performed. The masking agent 30 may be a photosensitive material or an insulating material. The masking agent 30 may be, for example, a photoresist. The masking agent 30 is entirely applied on the upper surfaces of the anodic aluminum oxide plate 10 and the main metal layer A so that the main metal layer A is not exposed to the outside. Then, the masking agent 30 is subjected to exposure and development processes to form an open area through which a surface area of the intermediate portion 112 of each of the pin bodies 110 is exposed.

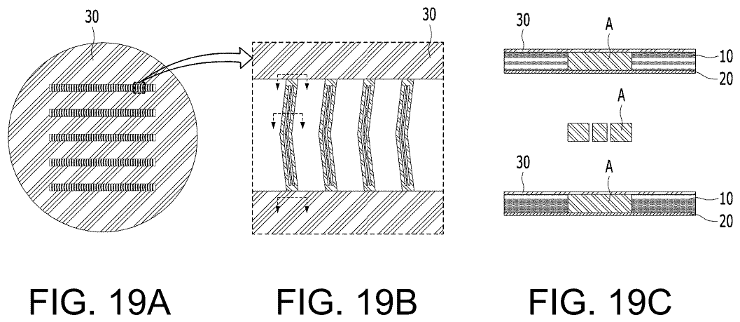

Referring to FIGS. 19A to 19C, FIG. 19A is a plan view illustrating the anodic aluminum oxide plate 10, FIG. 19B is an enlarged view of a portion of FIG. 19A, and FIG. 19C is a sectional view illustrating the first end portion 111, the intermediate portion 112, and the second end portion 113 illustrated in FIG. 19B.

As illustrated in FIGS. 19A to 19C, the step of exposing the surface of the intermediate portion 112 of each of the pin bodies 110 by removing the anodic aluminum oxide film and the seed layer 20 in the open area formed in the previous step. The anodic aluminum oxide film in the open area is removed using an etchant that selectively reacts only with the anodic aluminum oxide film. Next, the step of removing the seed layer 20 present on a lower surface of the intermediate portion 112 of each of the pin bodies 110 is performed. With this process, the intermediate portion 112 of each of the pin bodies 110 has a structure in which all the upper, lower, and side surfaces thereof are exposed.

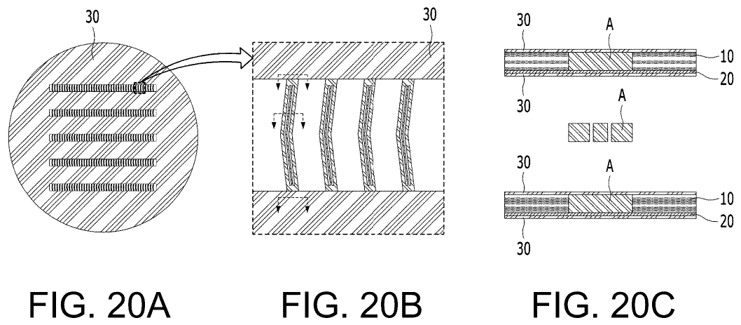

Referring to FIGS. 20A to 20C, FIG. 20A is a plan view illustrating the anodic aluminum oxide plate 10, FIG. 20B is an enlarged view of a portion of FIG. 20A, and FIG. 20C is a sectional view illustrating the first end portion 111, the intermediate portion 112, and the second end portion 113 illustrated in FIG. 20B.

As illustrated in FIGS. 20A to 20C, the step of forming the masking agent 30 on the lower surface of the anodic aluminum oxide plate 10 except for the intermediate portion 112 of each of the pin bodies 110 is performed. The masking agent 30 is formed on a lower surface of the seed layer 20 under the anodic aluminum oxide plate 10 except for the intermediate portion 112 of each of the pin bodies 110.

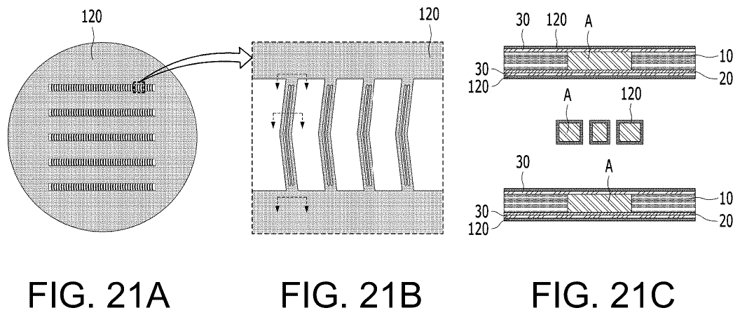

Referring to FIGS. 21A to 21C, FIG. 21A is a plan view illustrating the anodic aluminum oxide plate 10, FIG. 21B is an enlarged view of a portion of FIG. 21A, and FIG. 21C is a sectional view illustrating the first end portion 111, the intermediate portion 112, and the second end portion 113 illustrated in FIG. 21B.

As illustrated in FIGS. 21A to 21C, the step of forming the insulating coating 120 on the surface of the intermediate portion 112 of each of the pin bodies 110 is performed. The insulating coating 120 may be an inorganic insulating coating or an organic insulating coating (including parylene resin), and may be formed using a coating method such as electrodeposition coating, deposition coating (CVD, ALD, etc.), or wet coating. The insulating coating 120 is entirely formed on the exposed surfaces. At this time, the anodic aluminum oxide film of the first and second end portions 111 and 113 functions as a barrier preventing the insulating coating 120 from penetrating into the first and second end portions 111 and 113. The insulating coating 120 is formed on the surface of the intermediate portion 112 of each of the pin bodies 110, and is also formed on inner walls of holes 115 formed in the intermediate portion 112. The insulating coating 120 may also be formed on the upper and lower surfaces of the anodic aluminum oxide plate 10.

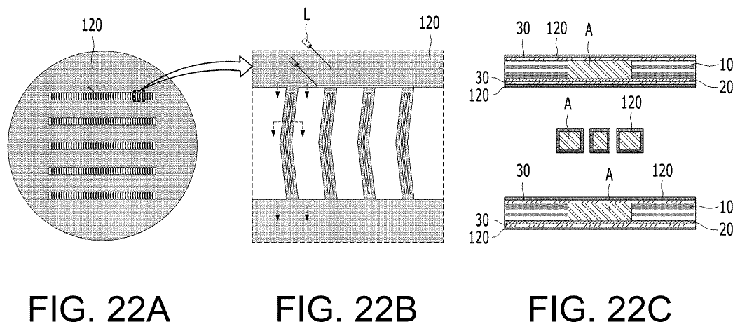

Referring to FIGS. 22A to 22C, FIG. 22A is a plan view illustrating the anodic aluminum oxide plate 10, FIG. 22B is an enlarged view of a portion of FIG. 22A, and FIG. 22C is a sectional view illustrating the first end portion 111, the intermediate portion 112, and the second end portion 113 illustrated in FIG. 22B.

As illustrated in FIGS. 22A to 22C, the step of forming a boundary area separating the insulating coating 120 of the intermediate portion 112 from the first end portion 111 using a laser L is performed. Here, the boundary area may be formed using a sandblasting method other than the laser L, and other physical or chemical methods may be used. The masking agent 30 is exposed through the boundary area.

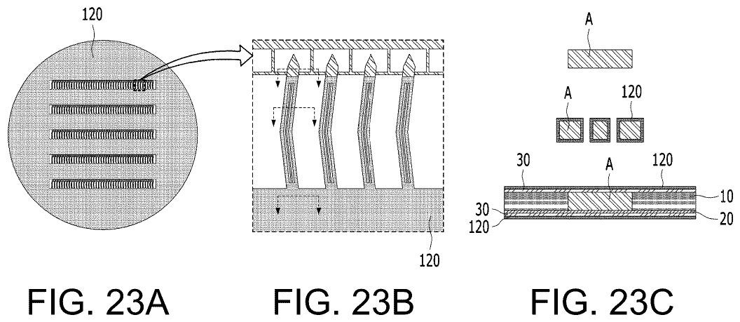

Referring to FIGS. 23A to 23C, FIG. 23A is a plan view illustrating the anodic aluminum oxide plate 10, FIG. 23B is an enlarged view of a portion of FIG. 23A, and FIG. 23C is a sectional view illustrating the first end portion 111, the intermediate portion 112, and the second end portion 113 illustrated in FIG. 23B.

As shown in FIGS. 23A to 23C, the step of exposing the first end portion 111 of each of the pin bodies 110 by removing the insulating coating 120 of the first end portion 111 is performed. In the previous step, the insulating coating 120 is formed not only on the intermediate portion 112 of each of the pin bodies 110 but also on the upper surface of the peripheral area thereof. Therefore, a process of removing the insulating coating 120 of the first end portion 111 of each of the pin bodies 110 is performed. When the masking agent 30 is removed by injecting a masking agent etchant into the boundary area, the insulating coating 120 present on the upper surface thereof is removed together. After that, the anodic aluminum oxide plate 10 and the seed layer 20 in the area including the first end portion 111 are also removed using respective etchants.

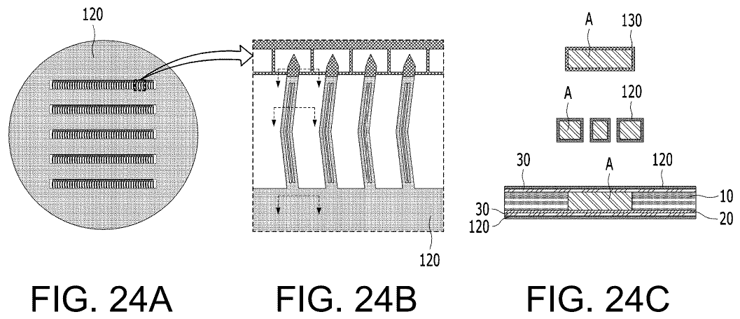

Referring to FIGS. 24A to 24C, FIG. 24A is a plan view illustrating the anodic aluminum oxide plate 10, FIG. 24B is an enlarged view of a portion of FIG. 24A, and FIG. 24C is a sectional view illustrating the first end portion 111, the intermediate portion 112, and the second end portion 113 illustrated in FIG. 24B.

As illustrated in FIGS. 24A to 24C, the step of forming the functional coating 130 on the surface of the first end portion 111 of each of the pin bodies 110 is performed. The functional coating 130 is formed on the upper, lower, and side surfaces of the first end portion 111 of each of the pin bodies 110 to surround the pin body 110. The functional coating 130 may be formed on the surface of the first end portion 111 of each of the pin bodies 110 by electroplating. Since support frames 200 of the module area are connected to each other through the main metal layer A, when an electrode for electroplating is connected to the main metal layer A of a part of the module area, the functional coating 130 is collectively formed on the surfaces of the first end portion 111 of each of the pin bodies 110.

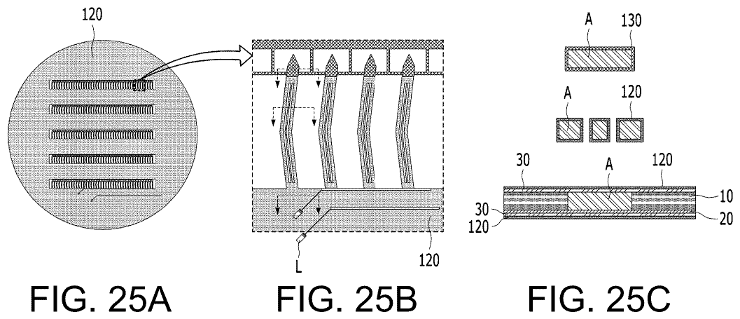

Referring to FIGS. 25A to 25C, FIG. 25A is a plan view illustrating the anodic aluminum oxide plate 10, FIG. 25B is an enlarged view of a portion of FIG. 25A, and FIG. 25C is a sectional view illustrating the first end portion 111, the intermediate portion 112, and the second end portion 113 illustrated in FIG. 25B.

As illustrated in FIGS. 25A to 25C, the step of forming a boundary area separating the insulating coating 120 of the intermediate portion 112 from the second end portion 114 using the laser L is performed. When the masking agent 30 is removed by injecting a masking agent etchant into the boundary area, the insulating coating 120 present on the upper surface thereof is removed together. After that, the remaining anodic aluminum oxide plate 10 and seed layer 20 are all removed using respective etchants to obtain an electro-conductive contact pin module.

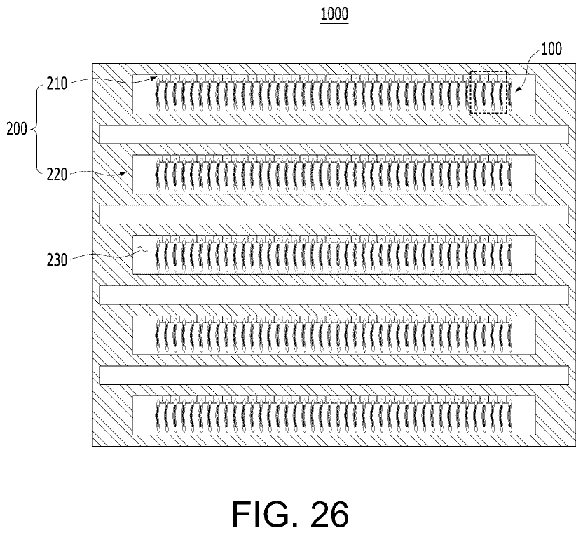

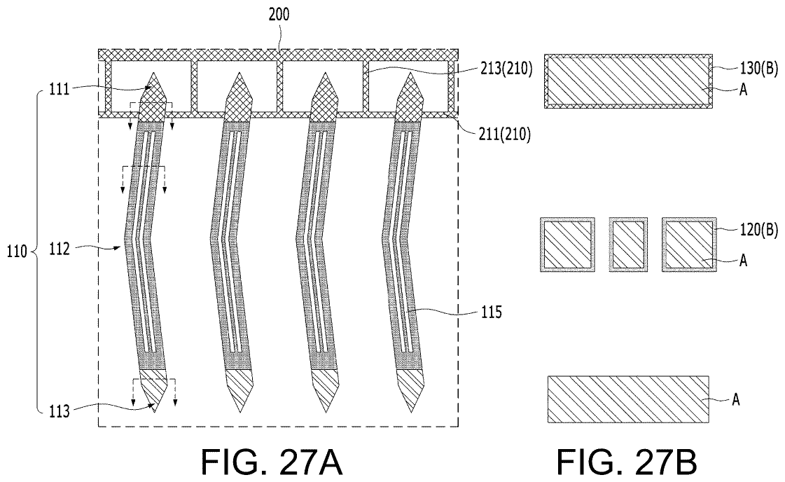

FIG. 26 is a plan view illustrating an electro-conductive contact pin module 1000. FIG. 27A is an enlarged view of a portion of FIG. 26, and FIG. 27B is a sectional view illustrating a first end portion 111, an intermediate portion 112, and a second end portion 113 illustrated in FIG. 27A. Referring to FIG. 26 and FIGS. 27A and 27B, each electro-conductive contact pin 100

constituting the electro-conductive contact pin module 1000 includes a pin body 110 including the first and second end portions 111 and 113 and the intermediate portion 112 between the first and second end portions 111 and 113, an insulating coating 120 formed on a surface of the intermediate portion 112 of the pin body 110, and a functional coating 130 formed on a surface of the first end portion 111 of the pin body 110.

The electro-conductive contact pin 100 according to the second embodiment of the present disclosure includes the first and second end portions 111 and 113 and the intermediate portion 112 between the first and second end portions 111 and 113. The first end portion 111 is further provided with the functional coating 130 on the surface thereof in addition to the material constituting the second end portion 113, and the intermediate portion 112 is further provided with the insulating coating 120 in addition to the material constituting the second end portion 113.

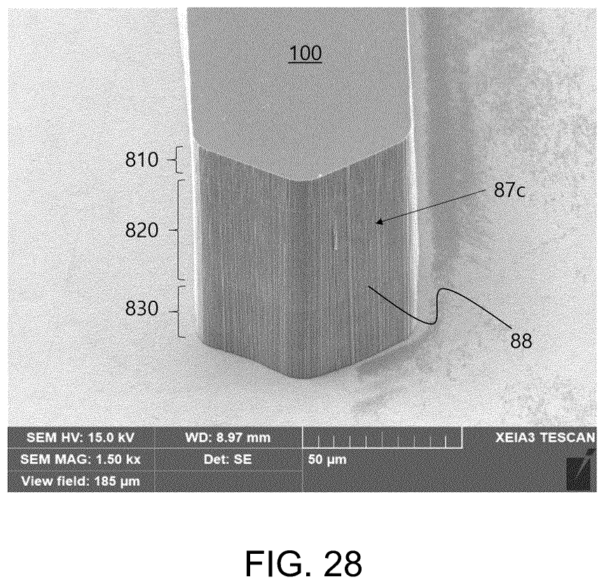

Since the electro-conductive contact pins 100 according to the first and second embodiments of the present disclosure described above are manufactured by using the anodic aluminum oxide plate 10 as a mold, a plurality of fine trenches 88 are formed on at least one surface of the electro-conductive contact pin 100. Referring to FIG. 28, the fine trenches 88 are formed on a side surface 87c of the second end portion 113 of the electro-conductive contact pin 100. On the side surface 87c of the second end portion 113 of the electro-conductive contact pin 100, the fine trenches 88 are formed in a long groove shape extending in the thickness direction of the electro-conductive contact pin 100. Here, the thickness direction of the electro-conductive contact pin 100 means a direction in which the main metal layer A grows during electroplating. The fine trenches 88 are formed on the entire side surface 87c of the second end portion 113 of the electro-conductive contact pin 100, but are not formed on the upper and lower surfaces except for the side surface 87c.

The fine trenches 88 have a depth in the range of 20 nm to 1 μm and a width in the range of 20 nm to 1 μm. Here, because the fine trenches 88 are resulted from the formation of pores formed during the manufacture of the anodic aluminum oxide plate 10, the width and depth of the fine trenches 88 are equal or less than the diameter of the pores formed in the anodic aluminum oxide plate 10. On the other hand, in the process of forming the openings 11 in the anodic aluminum oxide plate 10, portions of the pores of the anodic aluminum oxide plate 10 may be crushed by an etchant to at least partially form a fine trench 88 having a depth greater than the diameter of the pores formed during the anodization.

Since the anodic aluminum oxide plate 10 includes a large number of pores, at least portions of the anodic aluminum oxide plate 10 are etched to form the openings 11, and the main metal layer A is formed in the openings 11 by electroplating, the fine trenches 88 are formed on the side surface 87c of the electro-conductive contact pin 100 as a result of contact between the electro-conductive contact pin 100 and the pores of the anodic aluminum oxide plate 10.

Unlike the second end portion 113, the coating layer B is provided on the first end portion 111 and the intermediate portion 112. As the coating layer B is formed on the first end portion 111 and the intermediate portion 112, the side surface 87c of the second end portion 113 is different in roughness range from a side surface of the first end portion 111 and from the intermediate portion 112. With the configuration in which the fine trenches 88 are provided on the side surface of the second end portion 113 making contact with the object to be inspected, the contact resistance of the electro-conductive contact pin 100 can be reduced upon contact with the object to be inspected.

Referring to FIG. 28, the electro-conductive contact pin 100 may be provided in a structure in which three metal layers are stacked. A first layer 810 and a third layer 830 have excellent hardness characteristics to provide excellent mechanical elasticity to the electro-conductive contact pin 100, and a second layer 820 provides electrical characteristics of excellent electrical conductivity. The first layer 810 and the third layer 830 may be made of nickel (Ni) or a nickel (Ni) alloy, and the second layer 820 may be made of copper (Cu) or a copper (Cu) alloy. With this configuration, it is possible to provide an electro-conductive contact pin having excellent mechanical properties and excellent electrical properties at the same.

According to the first and second embodiment of the present disclosure, there is one technical feature in that the step of forming the main metal layer A and the step of forming the coating layer B are performed in units of the anodic aluminum oxide plate 10. The anodic aluminum oxide plate 10 functions as a mold in manufacturing the pin body 110 of the electro-conductive contact pin 100, and functions to support the module 1000 in forming the coating layer B. The anodic aluminum oxide plate 10 is manufactured to have the same size as a silicon wafer so that the electro-conductive contact pin 100 can be manufactured using process equipment that processes the silicon wafer.

When a plurality of electro-conductive contact pins 100 are collectively manufactured using the anodic aluminum oxide plate 10, the production rate can be improved and the coating layer B can be uniformly formed on all the electro-conductive contact pins 100, compared to removing the electro-conductive contact pins 100 and individually forming the coating layer B thereon. In addition, since the electro-conductive contact pins 100 are fixed to the support frame 200 even after the formation of the coating layer B, the electro-conductive contact pins 100 can be easily inserted into guide plates in a later process.

Although the exemplary embodiments of the present disclosure have been described for illustrative purposes, those skilled in the art will appreciate that various modifications, additions, and substitutions are possible, without departing from the scope and spirit of the present disclosure as disclosed in the accompanying claims.

### DESCRIPTION OF THE REFERENCE NUMERALS IN THE DRAWINGS

100: electro-conductive contact pin
110: pin body
120: insulating coating
130: functional coating
200: support frame
1000: electro-conductive contact pin module

1.-9. (canceled)

10. An electro-conductive contact pin module, comprising:
a support frame including connecting portions; and
electro-conductive contact pins provided in the support frame through the connecting portions,
wherein each of the electro-conductive contact pins comprises:
a pin body including first and second end portions and an intermediate portion between the first and second end portions;
an insulating coating formed on a surface of the intermediate portion of the pin body; and
a functional coating formed on a surface of the first end portion of the pin body.

11. The electro-conductive contact pin module of claim 10, wherein the functional coating is formed on at least a portion of the support frame.

12. An electro-conductive contact pin, comprising:
a pin body including first and second end portions and an intermediate portion between the first and second end portions;
an insulating coating formed on a surface of the intermediate portion of the pin body; and
a functional coating formed on a surface of the first end portion of the pin body.

13. The electro-conductive contact pin of claim 12, wherein the functional coating is continuously formed on the surfaces of the intermediate portion and the first end portion of the pin body, and is not formed on a surface of the second end portion.

14. The electro-conductive contact pin of claim 12, wherein the functional coating is formed only on the first end portion.

15. The electro-conductive contact pin of claim 12, wherein the functional coating is made of Au.

16. The electro-conductive contact pin of claim 12, wherein a fine trench extending in a thickness direction of the electro-conductive contact pin is provided on a side surface of the second end portion.

17. The electro-conductive contact pin of claim 12, wherein a side surface of the second end portion is different in roughness range from a side surface of the first end portion.

18. The electro-conductive contact pin of claim 12, wherein a side surface of the second end portion is different in roughness range from a side surface of the intermediate portion.

19. (canceled)

20. An electro-conductive contact pin, comprising
a pin body including first and second end portions and an intermediate portion between the first and second end portions,
wherein the first end portion is further provided with a functional coating on a surface thereof in addition to a material constituting the second end portion, and
the intermediate portion is further provided with an insulating coating on a surface thereof in addition to a material constituting the first end portion.

21. (canceled)
